(19) United States
(12) Patent Application Publication
(10) Pub. No.: US 2006/0263992 A1
(43) Pub. Date: Nov. 23, 2006

(54) Method of forming the N-MOS and P-MOS gates of a CMOS semiconductor device

(76) Inventors: Chien-Hao Chen, Chuangwei Township (TW); Chun-Feng Nieh, Baoshan Township (TW); Karen Mai, Jhonghe City (TW); Tze-Liang Lee, Hsinchu (TW)

Correspondence Address: SLATER & MATSIL, L.L.P., 17950 PRESTON ROAD, SUITE 1000, DALLAS, TX, 75252, US

(21) Appl. No.: 11/133,967

(22) Filed: May 20, 2005

(51) Int. Cl. H01L 21/336

(52) U.S. Cl. 438/301

(57) ABSTRACT

A method for forming the N-MOS and P-MOS transistor regions of a CMOS device having reduced depletion of the N and P dopants in the polysilicon gate and reduced penetration of the N and P dopants through the oxide layer and into the channel regions of the N-MOS and the P-MOS transistor. The improvements are accomplished by a new implantation treatment of the polysilicon gate layer prior to implanting the polysilicon layer with the N-type dopant and the P-type dopant for purposes of forming the transistor gates. The implantation treatment prior to the N-type dopant and P-type dopant implantation, includes a first implantation of Ge and/or an inert gas and a second implantation of carbon or fluorine.

### TECHNICAL FIELD

The present invention relates to a method of fabricating N-MOS transistor gates and P-MOS transistor gates in a CMOS semiconductor device, and more particularly to fabricating said gates with minimum polysilicon N-type and/or P-type dopant depletion. Minimizing the dopant depletion is accomplished by reducing the migration or penetration of the N-type and P-type dopants through the oxide layer and into the channel region of the transistors. A high level of dopant improves the performance of the device.

### BACKGROUND

As the scaling of the dimensions of a CMOS device gets smaller and smaller, very shallow vertical junctions are required to maintain a short channel effect in the N-MOS and P-MOS transistors. Unfortunately, the shallow vertical junctions result in excessive depletion or diffusion of the N-type or P-type dopant from the polysilicon gate through the oxide layer and into the channel region of the transistors. This in turn leads to degraded current capabilities. One approach to counter the excessive depletion as described in the publication of U.S. Patent Application 2004/0102013 A1 to Hwang, et al. is to dope the NMOS source drain junction by implanting carbon or fluorine. However, phosphorous is typically used for the N-dopant, and boron as the P-dopant. These materials have very high diffusion rates or properties with poor margins or boundaries. This high diffusion rate along with excessive dopant levels of the polysilicon layer results in even greater migration of dopant materials into the gate oxide and channel regions. Thus, the reliability of the gate oxide is degraded, and the threshold voltage of the transistors are shifted or changed. Attempts to use nitrogen to inhibit the diffusion of the dopant, as described in U.S. Pat. No. 5,959,333 to Gardner, et al., have not been particularly helpful as the nitrogen degrades the activation level of the dopant, which also leads to limits to performance gain.

### SUMMARY OF THE INVENTION

These and other problems are generally solved or circumvented, and technical advantages are generally achieved, by embodiments of the present invention, which provide methods of forming a CMOS device comprising the steps of providing a substrate covered by a layer of polycrystalline silicon (polysilicon). The polysilicon layer defines at least one of a first region for forming a gate for an N-MOS transistor or a second region for forming the gate for a P-MOS transistor. Prior to forming the transistor gates, germanium (Ge) or an inert gas is implanted into the polysilicon layer. Suitable inert gases include neon (Ne), argon (Ar), krypton (Kr), xeon (Xe), and radon (Rn). In addition to implantation of Ge or one of the inert gases, at least one of carbon and/or fluorine is also implanted into the polysilicon layer.

The typical N-type dopants, such as phosphorous or arsenic, and the typical P-type dopants, such as boron, are then implanted into the appropriate N-MOS or P-MOS regions of the polysilicon layer by sequentially forming protective layers of photoresist to protect and expose the first or N-MOS regions and second or P-MOS regions of the polysilicon layer as necessary.

After implantation of the dopants is completed and the protective layers of photoresist have been removed, N-MOS portions of the polysilicon layer can be patterned and etched to form the N-MOS transistor gates, and the P-MOS portions of the polysilicon layer can be patterned and etched to form the P-MOS transistor gates. The appropriate source and drain region can then be formed by additional implantation of N-MOS and P-MOS dopant materials and the formation of spacers on the sides of the poly gates.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 illustrates a substrate, oxide layer and a polysilicon layer suitable for use with the methods of the present invention;

FIGS. 2-5 illustrate a first embodiment of the inventive method;

FIGS. 6-11 illustrate a second embodiment of the inventive method; and

FIGS. 12 and 13 illustrate the formation of PMOS and NMOS transistors in a CMOS device formed with gates doped according to the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

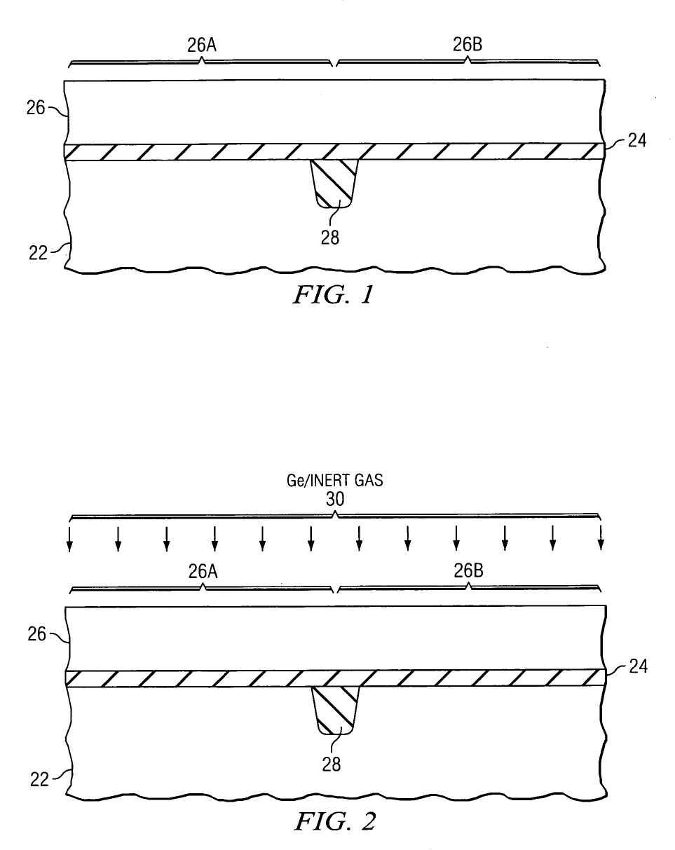

The present invention discloses a method of doping prior art structures comprising a layer of polycrystalline silicon (hereinafter polysilicon) such as shown in FIG. 1 prior to formation of CMOS gates. The dopant technique of the invention minimizes polysilicon depletion problems by enabling a higher polysilicon doping level, and minimizing the dopant penetration into and through the gate oxide.

Referring now to FIG. 1 there is illustrated a structure 20 suitable for having a CMOS device formed thereon. Structure 20 comprises a semiconductor substrate 22 covered by a gate oxide layer 24, which in turn is covered by the polycrystalline silicon layer 26 that will be patterned and etched to form N-MOS and/or P-MOS transistor gates and particularly such N-MOS and P-MOS transistor gates for a CMOS device. Substrate 22 may comprise any suitable known material, and as an example only, substrate 22 may comprise a layer of lightly doped single crystalline silicon formed over a heavily doped layer. The lightly doped layer may be doped with either or both of an N-type or P-type dopant. The gate oxide or dielectric layer 24 typically comprises silicon dioxide formed by thermal oxidation. The layer of gate material 26 is preferably polycrystalline silicon that may be deposited over the gate oxide 26 by chemical-vapor deposition process or any other suitable method. Also, an isolation oxide structure 28 is shown as being formed in substrate 22 to divide the substrate into an N-MOS area 26a and a P-MOS area 26b.

FIGS. 2-5 illustrate a first embodiment of the invention, and as shown in FIG. 2, the structure 20 as discussed with respect to FIG. 1 is subjected to a pre-amorphorized implantation, as indicated by arrows 30, of germanium (Ge) or an inert gas, such as for example, neon (Ne), argon (Ar), krypton (Kr), xeon (Xe), and radon (Rn). Alternately, the implantation 30 illustrate by arrows 30 may comprise both Ge and one of the inert gases. The implantation step may be carried out using an energy level of between about 10 KeV and about 100 KeV so as to achieve an implantation dose of between about 1e13 to about 1e16, which will depend on the thickness of the polysilicon layer.

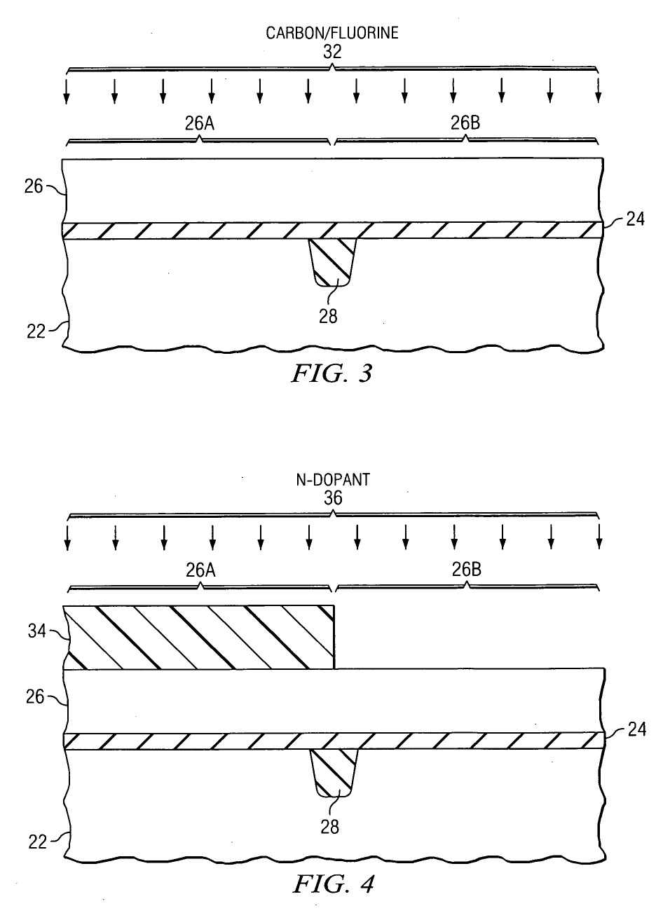

After implantation of the Ge and/or inert gases as indicated by arrows 30, substrate 20 is subjected to further implantation of carbon and/or fluorine, as illustrated in FIG. 3 and as indicated by arrows 32, for purposes of suppressing the depletion of the N-type and P-type dopants from the polysilicon gates after their formation by migration or penetration of the dopants through the oxide layer 24 and into the transistor channel regions. Thus, the carbon and/or fluorine indicated by arrows 32 is for purposes of reducing the diffusion of dopants and to enhance the activation. Implantation of the carbon and/or fluorine may be carried out using an energy level of between 5 KeV to about 100 KeV so as to achieve an implantation dose of the carbon and fluorine of about 1e13 to 1e16.

After implantation of both the Ge and/or inert gas, indicated by arrows 30 in FIG. 2, and the carbon and/or fluorine, indicated by arrows 32 in FIG. 2, a first layer of photoresist or other protective layer 34 is formed and patterned over the polysilicon structure as shown in FIG. 4. The protective layer 34 protects the P-MOS area 26a while exposing the N-MOS area 26b. Also as shown in FIG. 4, structure 20 is then subjected to implantation of an N-dopant, as indicated by arrows 36, so as to dope the N-MOS portion 26b of the layer of polysilicon in a manner suitable for forming the gate of an N-MOS transistor. As an example, the N-dopant is typically phosphorous or arsenic having a dose level of ranging between 1e13 and 1e16. After implantation of the N-dopant, the photoresist patterned layer 34 is removed.

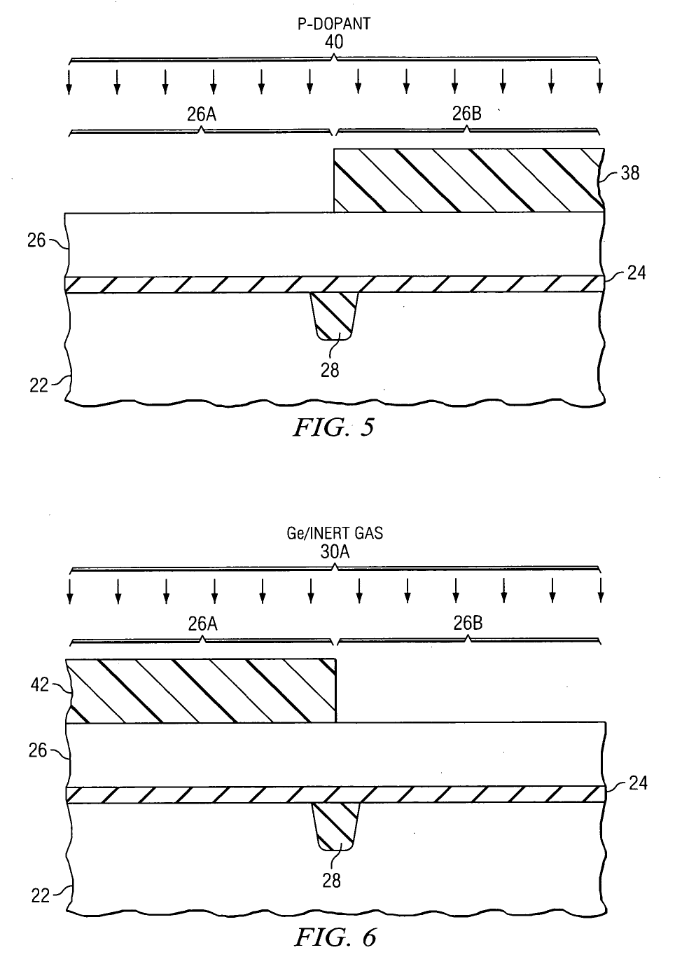

Referring now to FIG. 5, it is seen that a second layer of photoresist 38 is patterned so as to protect the N-MOS region 26b of the polysilicon layer and expose the P-MOS region 26a. Structure 20 is then subjected to a P-dopant implantation, such as for example boron, so as to achieve a dose level ranging from 1e13 to 1e16. The implantation of the P-MOS dopant is indicated by arrows 40. After completing the implantation of the P-type dopant into region 26a, the photoresist or protective layer 38 is removed.

Thus as will be appreciated by those skilled in the art, the implantation of the carbon and/or fluorine enables a higher dose implantation of both N and P type dopants, which of course means that the resistance and the depletion of the gate oxide poly interface is effectively reduced and thereby significantly improves the device's current drive. However, as will also be appreciated by those skilled in the art, predoping with only the carbon and fluorine dopants typically results in the highly diffusible N-type and P-type dopants, a reduced activation level and poor abruptness or cutoff region. This leads to a significant penetration of the dopants into the gate oxide, and in some instances through the oxide and into the channel region. However, by also including the implantation of the Ge or an inert gas as taught by this invention, the diffusion of the N-type and P-type dopants into the gates of the transistor is substantially inhibited without also degrading the dopant activation level. The performance gain will be limited if the dopant activation level is degraded.

After removal of the second layer of photoresist or protective layer 38, the structure 20 may be subjected to thermal annealing for purposes of activating the dopant. Typically, a thermal anneal for these purposes occurs at a temperature of between about 600° centigrade to 1300° centigrade for a period of between 1 millisecond to 10 hours. However, the thermal annealing step may be postponed until further completion of the CMOS device.

At this point, it will be appreciated by those skilled in the art that the polysilicon layer may be patterned to form the P-MOS and N-MOS gates for the CMOS device and the other elements of the transistor such as the source, the drains, and the spacers. Since these steps are the same for the structure 20 formed according to the above discussed method, as well as for the embodiments discussed below, details of patterning of the polysilicon spacer formation of the source, drain and so forth will be described hereinafter.

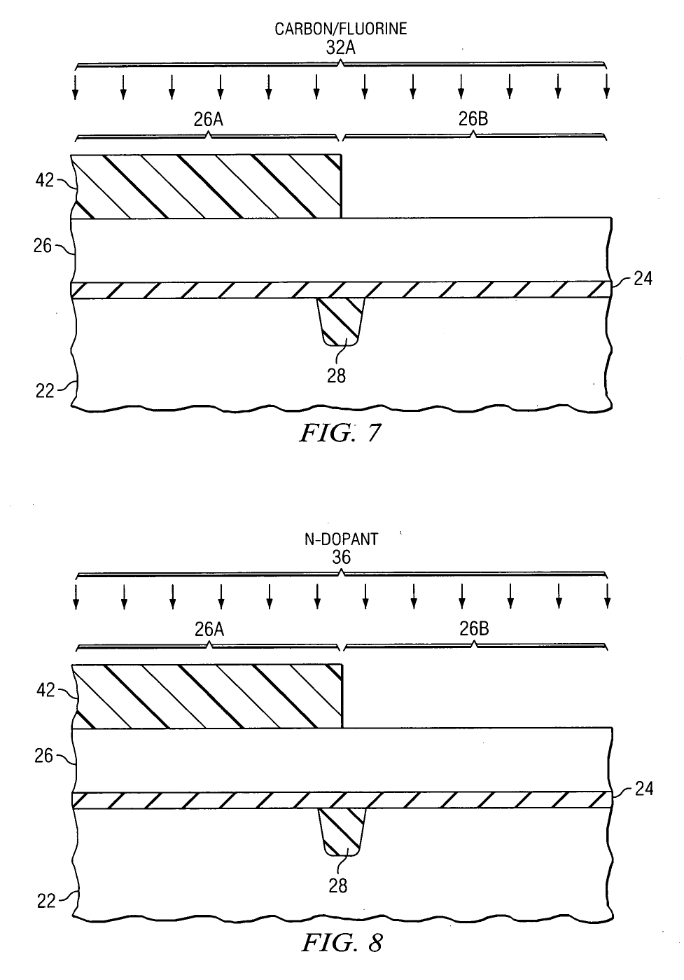

Referring now to FIGS. 6-11, there is illustrated the method of a second embodiment of the invention. FIG. 6 illustrates a structure 20a. The structure 20a is similar to the structure in FIG. 1, and elements of the structure of FIG. 6 that are identical or the same as elements of the structure of FIG. 1 carry the same reference numbers. Therefore, as shown, there is included a substrate 22 with a gate oxide layer 24 and a layer of polycrystalline silicon 26. It will also be appreciated, that there is indicated a implantation of Ge or an inert gas indicated by arrows 30. However, unlike the structure 20, the structure 20a further includes a patterned protective layer such as a patterned photoresist 42. As shown in FIG. 6, the patterned protective layer 42 is formed to protect the P-MOS portion 26a of the CMOS device while at the same time exposing the N-MOS 26b. Thus, as will be appreciated, implantation of the Ge and/or inert gas as indicated by arrows 30a occurs only at the N-MOS portion 26b of the polysilicon layer 26. Also as shown, arrows 32a of FIG. 7 illustrate the implantation of at least one of carbon or fluorine into the N-MOS portion 26b of the polysilicon layer 26. As will be appreciated, this is similar to the implantation discussed with respect to FIG. 2 of the first embodiment except that the photoresist or protective layer 42 is in place to prevent implantation of the carbon or fluorine into the P-MOS portion of the polysilicon layer.

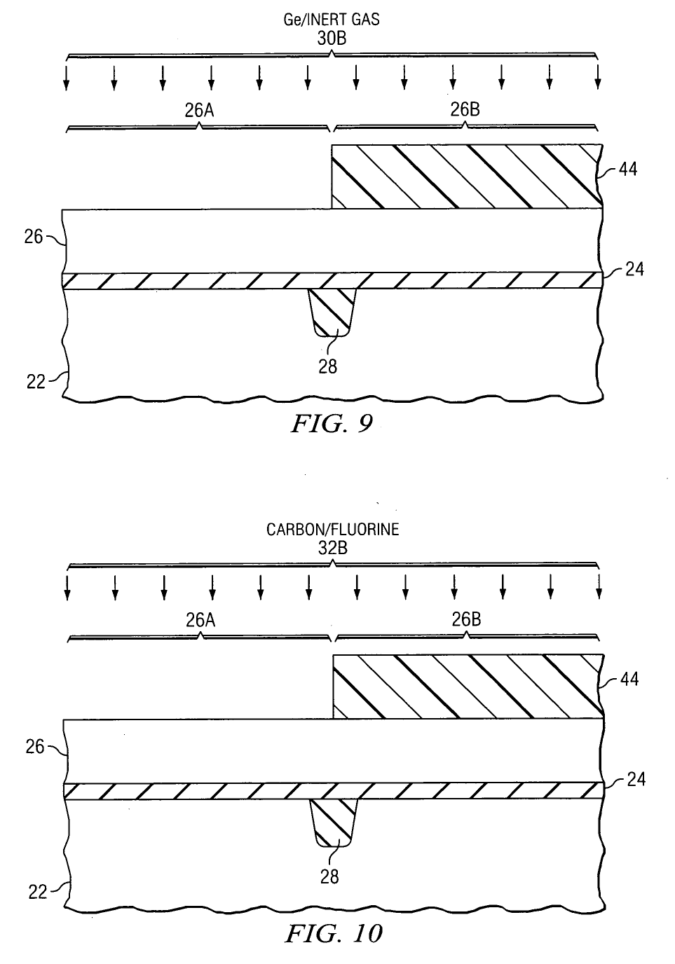

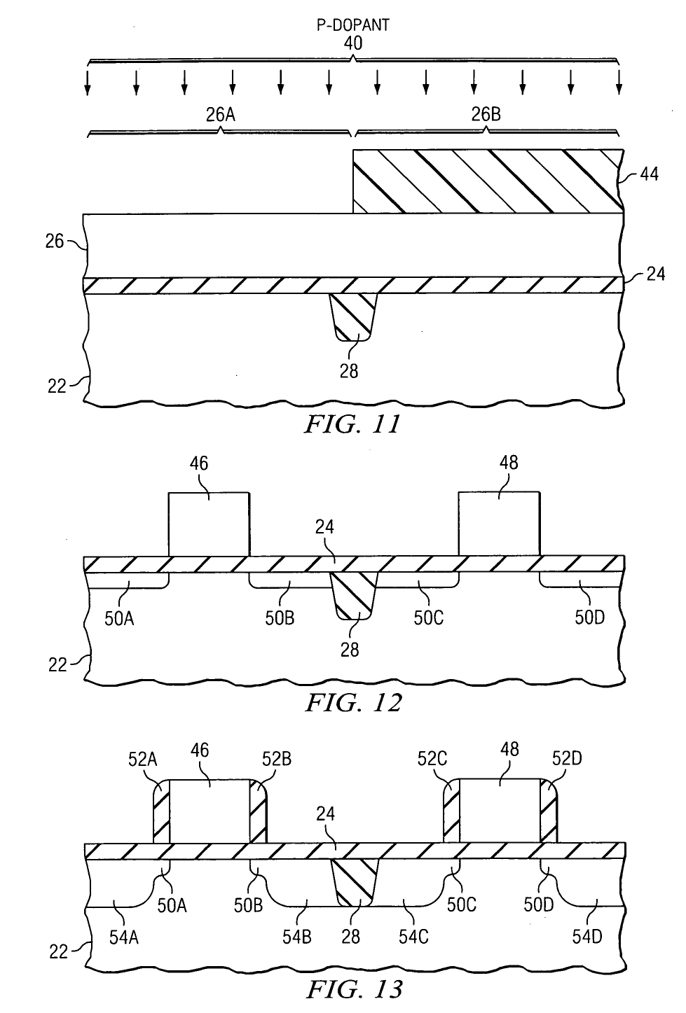

After implantation of the carbon, the fluorine, the Ge, and/or the inert gases into the N-MOS portion 26b of the polysilicon layer, the N-dopant, indicated by arrows 36 is also implanted in the same manner and under the same parameters as was discussed with respect to FIG. 4. After the implantation, the photoresist layer 42 is then removed and as shown in FIG. 9, a second patterned protective layer such as a photoresist layer 44 is formed over the top of the polysilicon layer. Photoresist layer 44 protects the N-MOS portion 26b of the polysilicon, which has already been implanted with Ge or an inert gas, fluorine, or carbon, and the N-type dopant from further implantation. At the same time, the P-MOS portion 26a of the polysilicon layer 26 is exposed. Thus, also as shown in FIG. 9, at least one of Ge or an inert gas, such as discussed above with respect to FIG. 6, is implanted into the P-MOS portion 26a of the silicon as indicated by arrows 30b. Similar, as shown in FIG. 10, at least one of the materials carbon or fluorine is also implanted into the P-MOS portion 26a of the polysilicon layer 26 as indicated by arrows 32b. Then, as shown in FIG. 11, the P-type dopant, indicated by arrows 38, is implanted in the same manner as was discussed above with respect to FIG. 5. At this point, as was discussed above with respect to embodiment 1, the structure 20a may be subjected to thermal annealing in the manner discussed above.

Thus as will be appreciated, there have been described two embodiments forming structures doped polysilicon suitable for forming the N-MOS and P-MOS gates of a CMOS device.

Therefore, referring to FIG. 12, there is shown the patterning of the N-type doped polysilicon and the P-type doped polysilicon to form an N-MOS gate 46 and a P-MOS gate 48 on the structure. After patterning and forming the N-MOS and P-MOS gates, there is further implantation of P-type dopant and N-type dopant through the oxide layer 24 and into the substrate 22 to form lightly doped source and drain areas 50a, 50b, 50c, and 50d for the N-MOS and P-MOS transistors. FIG. 13 illustrates the formation of spacers 52a, 52b, 52c, and 52d on the sides of the N-MOS and P-MOS gates and further illustrates still additional implantation of P-dopant or N-dopant to complete the formation of the fully doped source and drain areas 54a, 54b, 54c, and 54d in these regions.

Although the present invention and its advantages have been described in detail, it should be understood that various changes, substitutions and alterations can be made herein without departing from the spirit and scope of the invention as defined by the appended claims. For example, it will be readily understood by those skilled in the art that the methods may be varied while remaining within the scope of the present invention.

Moreover, the scope of the present application is not intended to be limited to the particular embodiments of the methods and steps described in the specification. As one of ordinary skill in the art will readily appreciate from the disclosure of the present invention, processes, or steps, presently existing or later to be developed, that perform substantially the same function or achieve substantially the same result as the corresponding embodiments described herein may be utilized according to the present invention. Accordingly, the appended claims are intended to include within their scope such processes or steps.

What is claimed is:

1. A method of forming a CMOS device comprising the steps of:
providing a substrate covered by a layer of material for forming a gate electrode, said layer having a first region and a second region;
implanting at least one of carbon and fluorine into said layer of material forming a gate electrode;
implanting one of said first and second regions of said gate electrode material with an N-dopant; and
implanting the other one of said first and second regions of said gate electrode material with a P-dopant.

2. The method of claim 1, wherein said gate electrode material is polysilicon.

3. The method of claim 1 further comprising implanting at least one of Ge and an inert gas into said layer of polysilicon before the step of implanting carbon and fluorine.

4. The method of claim 1 wherein said inert gas is selected from the group consisting of Ne, Ar, Kr, Xe, and Rn.

5. The method of claim 1 wherein said step of implanting one of carbon and fluorine comprises implanting both carbon and fluorine into said layer.

6. The method of claim 1 wherein said implantation of one of carbon or fluorine is implanted with a dose of between about 1e14 and 2e16.

7. The method of claim 1 wherein said implantation of an N-dopant or P-dopant is implanted with a dose of between about 1e13 and 1e16.

8. The method of claim 3 wherein said implantation of one of Ge or an inert gas is implanted with a dose of between about 1e13 and 1e16.

9. The method of claim 1 wherein said N-dopant comprises one of phosphorous or arsenic.

10. The method of claim 1 wherein said P-dopant comprises boron.

11. The method of claim 3 further comprising forming a protective layer to cover one of said first and second regions and to leave the other one of said first and second regions exposed prior to said step of implanting at least one of said N-dopants and said P-dopants.

12. The method of claim 11 wherein said protective layer is formed subsequent to said step of implanting said at least one of said Ge or an inert gas, and said step of implanting said at least one of carbon or fluorine.

13. The method of claim 11 and further comprising removing said protective layer after implanting one of said N-dopant and P-dopant and then forming another protective layer for covering the other one of said first and second regions prior to said step of implanting the other one of said N-dopants and said P-dopants.

14. The method of claim 13 wherein both said protective layer and said another protective layer are formed subsequent to said step of implanting said at least one of Ge or an inert gas, and said step of implanting said at least one of carbon or fluorine.

15. The method of claim 11 wherein said protective layer is formed prior to said step of implanting said at least one of said Ge and an inert gas into said layer of silicon.

16. The method of claim 15 wherein said protective layer is removed subsequent to said step of implanting one of said first and second regions with one of said N-dopant and P-dopant, and said another protective layer is formed prior to said step of implanting said other one of said first and second regions with another one of said N-dopants and P-dopants.

17. The method of claim 11 wherein said patterned protective layer is formed prior to said step of implanting said at least one of carbon and fluorine into said layer of silicon.

18. The method of claim 16 wherein said patterned protective layer is formed prior to said step of implanting said at least one of carbon and fluorine into said layer of silicon.

19. The method of claim 1 further comprising the steps of patterning and forming first and second gates, said first and second gates formed one each in said first and second regions of said gate electrode material.

20. The method of claim 19 further comprising the step of forming spacers on each side of said first and second gates.
